(19) United States
(12) Patent Application Publication
(10) Pub. No.: US 2015/0221547 A1
(43) Pub. Date: Aug. 6, 2015

(54) HARDMASK FACETING FOR ENHANCING METAL FILL IN TRENCHES

(71) Applicants: STMICROELECTRONIC, INC., Coppell, TX (US); INTERNATIONAL BUSINESS MACHINES CORPORATION, Armonk, NY (US)

(72) Inventors: John C. Arnold, North Chathan, NY (US); Shyng-Tsong Chen, Rensselaer, NY (US); Yann Mignot, Slingerlands, NY (US); Muthumanickam Sankarapandian, Niskayuna, NY (US); Oscar van der Straten, Mohegan Lake, NY (US); Yunpeng Yin, Niskayuna, NY (US)

(73) Assignees: STMICROELECTRONIC, INC., Coppell, TX (US); INTERNATIONAL BUSINESS MACHINES CORPORATION, Armonk, NY (US)

(21) Appl. No.: 14/172,263

(22) Filed: Feb. 4, 2014

(51) Int. Cl. H01L 21/768; H01L 21/311

(52) U.S. Cl. CPC H01L 21/76802; H01L 21/7684; H01L 21/76877; H01L 21/31116; H01L 21/31144

(57) ABSTRACT

A stack of an interlevel dielectric (ILD) layer, a dielectric cap layer, and a metallic hard mask layer is formed on a substrate. The metallic hard mask layer can be patterned with a first pattern. A photoresist layer is formed over the metallic hard mask layer and is patterned with a second pattern. A combination of the first pattern and the second pattern is transferred into the ILD layer to form a dual damascene trench, which includes an undercut underneath the patterned dielectric cap layer. The metallic hard mask layer is removed and the dielectric cap layer is anisotropically etched to form faceted edges and removal of overhanging portions. A metallic material can be deposited into the dual damascene trench without formation of voids during a metal fill process.

### BACKGROUND

The present disclosure relates to a method of forming metal interconnect structure, and particularly to a method of enhancing a metal fill in a trench by employing a faceted hard mask, and structures for effecting the same.

As the minimum feature size continues to shrink with advancement of semiconductor technology, the width of trenches for forming metal line structures and/or metal via structures decrease accordingly. Because interlevel dielectric (ILD) materials are less resistant to etch chemistries than dielectric materials employed for hard mask layers, undercuts are formed underneath openings in the hard mask layers. Such undercuts impede filling of the trenches, and can cause formation of voids within metal line structures and/or metal via structures. Thus, a method is desired for preventing formation of voids during formation of metal line structures and metal via structures.

### SUMMARY

A stack of an interlevel dielectric (ILD) layer, a dielectric cap layer, and a metallic hard mask layer is formed on a substrate. The metallic hard mask layer can be patterned with a first pattern, which can be a via pattern. A photoresist layer is formed over the metallic hard mask layer and is patterned with a second pattern, which can be a line pattern. A combination of the first pattern and the second pattern is transferred into the ILD layer to form a dual damascene trench, which includes an undercut underneath the patterned dielectric cap layer. The metallic hard mask layer is removed and the dielectric cap layer is anisotropically etched to form faceted edges and removal of overhanging portions. A metallic material can be deposited into the dual damascene trench without formation of voids during a metal fill process.

According to an aspect of the present disclosure, a method of forming a metal interconnect structure is provided. A stack is formed over a substrate. The stack includes at least, from bottom to top, an interlevel dielectric layer and a dielectric cap layer over a substrate. The dielectric cap layer is patterned to form an opening therein. A trench is formed employing an anisotropic etch that anisotropically etches a material of the interlevel dielectric layer. The trench includes an undercut region that is formed in a step of the anisotropic etch directly underneath an overhang portion of the dielectric cap layer. The overhang portion of the dielectric cap layer is removed during another step of the anisotropic etch. A remaining portion of the dielectric cap layer overlies a top surface of the interlevel dielectric layer after the anisotropic etch.

### BRIEF DESCRIPTION OF THE SEVERAL VIEWS OF THE DRAWINGS

FIG. 1 is a schematic vertical cross-sectional view of a first exemplary structure after formation of a stack of an interlevel dielectric layer, a dielectric cap layer, and a metallic hard mask layer according to a first embodiment of the present disclosure.

FIG. 2 is a schematic vertical cross-sectional view of the first exemplary structure after patterning of the metallic hard mask layer with a first pattern employing a first photoresist layer according to the first embodiment of the present disclosure.

FIG. 2A a schematic vertical cross-sectional view of the first exemplary structure along the vertical plane A-A′ of FIG. 2.

FIG. 3 is a schematic vertical cross-sectional view of the first exemplary structure after formation of a second photoresist layer including a second pattern according to the first embodiment of the present disclosure.

FIG. 3A is a schematic vertical cross-sectional view of the first exemplary structure along the vertical plane A-A′ of FIG. 3.

FIG. 4 is a schematic vertical cross-sectional view of the first exemplary structure after a first step of transfer of a combination of the first pattern and the second pattern through the dielectric cap layer and the interlevel dielectric layer according to the first embodiment of the present disclosure. In this exemplary illustration, the first pattern has been transferred completely through the interlayer dielectric layer, but that is not strictly necessary. Common practices include both complete etch as illustrated here and partial etch of the ILD layer, with completion of the etch being provided in subsequent steps.

FIG. 4A is a schematic vertical cross-sectional view of the first exemplary structure along the vertical plane A-A′ of FIG. 4.

FIG. 5 is a schematic vertical cross-sectional view of the first exemplary structure after a second step of transfer of a combination of the first pattern and the second pattern through the dielectric cap layer and the interlevel dielectric layer according to the first embodiment of the present disclosure.

FIG. 5A is a schematic vertical cross-sectional view of the first exemplary structure along the vertical plane A-A′ of FIG. 4.

FIG. 6 is a schematic vertical cross-sectional view of the first exemplary structure after formation of dual damascene trenches according to the first embodiment of the present disclosure.

FIG. 6A is a schematic vertical cross-sectional view of the first exemplary structure along the vertical plane A-A′ of FIG. 6.

FIG. 7 is a schematic vertical cross-sectional view of the first exemplary structure after formation of line and via structures according to the first embodiment of the present disclosure.

FIG. 7A is a schematic vertical cross-sectional view of the first exemplary structure along the vertical plane A-A′ of FIG. 7.

FIG. 8 is a schematic vertical cross-sectional view of the first exemplary structure after formation of another level of metal interconnect structure according to the first embodiment of the present disclosure.

FIG. 9 is a schematic vertical cross-sectional view of a second exemplary structure after patterning of the metallic hard mask layer with a first pattern employing a first photoresist layer according to a second embodiment of the present disclosure.

FIG. 10 is a schematic vertical cross-sectional view of the second exemplary structure after application and patterning of a second photoresist layer according to the first embodiment of the present disclosure.

FIG. 11 is a scanning electron micrograph (SEM) of a sample manufactured employing a processing sequence of the present disclosure after deposition of a metallic material in a trench and prior to planarization.

### DETAILED DESCRIPTION

As stated above, the present disclosure relates to a method of enhancing a metal fill in a trench by employing a faceted hard mask, and structures for effecting the same. Aspects of the present disclosure are now described in detail with accompanying figures. It is noted that like and corresponding elements are referred to by like reference numerals. The drawings are not in scale. As used herein, ordinals such as “first” and “second” are employed to distinguish similar elements, and different ordinals may be employed across the specification and the claims to refer to a same element.

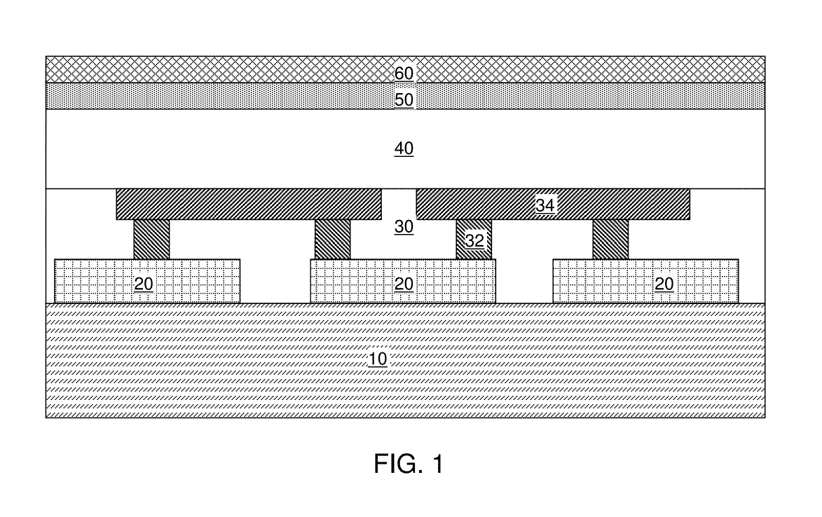

Referring to FIG. 1, a first exemplary structure according to a first embodiment of the present disclosure includes a substrate 10, at least one semiconductor device 20 formed on the substrate 10, and at least one underlying dielectric material layer 30 embedding underlying metal interconnect structures (32, 34). A stack of material layers (40, 50, 60) can be formed over the substrate 10 and the at least one underlying dielectric layer 30. As used herein, an “underlying” element refers to an element that is located underneath a reference element. The at least one underlying dielectric layer 30 and the underlying metal interconnect structure (32, 34) underlie the stack of material layers (40, 50, 60).

In one embodiment, the substrate 10 can be a semiconductor substrate. The semiconductor substrate includes a semiconductor material, which can be selected from, but is not limited to, silicon, germanium, silicon-germanium alloy, silicon carbon alloy, silicon-germanium-carbon alloy, gallium arsenide, indium arsenide, indium phosphide, III-V compound semiconductor materials, II-VI compound semiconductor materials, organic semiconductor materials, and other compound semiconductor materials. Typically, the semiconductor material includes silicon. The semiconductor substrate can be a bulk semiconductor substrate or a semiconductor-on-insulator (SOI) substrate. The at least one semiconductor device can be a field effect transistor, a bipolar transistor, a diode, a resistor, a capacitor, an inductor, an electrically programmable fuse, or any combination thereof.

The at least one underlying dielectric material layer 30 and the underlying metal interconnect structures (32, 34), if present, can be formed above the substrate 10. The at least one underlying dielectric material layer 30 can include any dielectric material as known in the art for embedding metal interconnect structures. For example, the at least one underlying-level dielectric layer 30 can include any dielectric material selected from doped silicate glass, undoped silicate glass, silicon nitride, silicon oxynitride, organosilicate glass (OSG), and nitrogen-doped OSG. The underlying metal interconnect structures (32, 34) embedded within the at least one underlying dielectric material layer 30 can be any metal interconnect structure known in the art. In one embodiment, the at least one underlying-level dielectric layer 30 and the underlying metal interconnect structures (32, 34) may be omitted.

The stack of material layers (40, 50, 60) can include, from bottom to top, an interlevel dielectric layer 40, a dielectric cap layer 50, and a metallic hard mask layer 60. The interlevel dielectric layer 40 includes a dielectric material, which can be a conventional dielectric material such as undoped silicon oxide (undoped silicate glass), doped silicon oxide (doped silicate glass), silicon oxynitride, silicon nitride, or a combination thereof. Alternatively, the dielectric material of the interlay dielectric layer 40 can be a low dielectric constant (low-k) material, which refers to a dielectric material having a dielectric constant less than the dielectric constant of silicon oxide, i.e., 3.9. Low dielectric constant materials that can be employed for the interlevel dielectric layer 40 include organosilicate glass including Si, C, O, H, and optionally N, and methylated-hydrogen silsesquioxane (MSQ). In one embodiment, the interlevel dielectric layer 40 includes porous or non-porous organosilicate glass. The low dielectric constant material can be deposited by chemical vapor deposition or by spin-coating, and can be porous or non-porous. The interlevel dielectric layer 40 is formed at an interconnect level, i.e., at a level in which metal interconnect structures are present.

The interlevel dielectric layer 40 can have a homogeneous composition throughout, or can include a vertical stack of multiple dielectric material layers each having a homogeneous composition. In one embodiment, the interlevel dielectric layer 40 can have a homogenous composition throughout the entirety thereof. The thickness of the interlevel dielectric layer 40 can be from 30 nm to 600 nm, and typically from 60 nm to 300 nm, although lesser and greater thicknesses can also be employed.

The dielectric cap layer 50 can be formed on the top surface of the interlevel dielectric layer 40. The dielectric cap layer 50 includes a dielectric material that is more etch resistant to the dielectric material of the interlevel dielectric layer 40. The dielectric cap layer 50 provides a capping structure for the interlevel dielectric layer 40, which can include a low-k dielectric material, and protects the interlevel dielectric material from damage, moisture, and/or chemical exposure during subsequent processing steps. For example, if the interlevel dielectric layer 40 includes a porous organosilicate glass or a non-porous organosilicate glass, the dielectric material of the dielectric cap layer 50 can be selected from silicon oxide, silicon oxynitride, silicon nitride, a nitrogen-containing non-porous organosilicate glass, and a dielectric metal oxide. The dielectric cap layer 50 can be deposited, for example, by chemical vapor deposition (CVD), atomic layer deposition, spin coating, or a combination thereof. The thickness of the dielectric cap layer 50 can be from 3 nm to 30 nm, although lesser and greater thicknesses can also be employed.

The metallic hard mask layer 60 can be formed on the top surface of the dielectric cap layer 50. The metallic hard mask layer 60 can be an elemental metal layer, an intermetallic alloy layer, a metallic nitride layer, a metallic carbide layer, or a combination or a stack thereof. The metallic hard mask layer 60 can be a single layer having a homogenous composition throughout, or can be a stack of multiple layers each having a homogeneous composition therein.

Non-limiting examples of elemental metals that can be employed for an elemental metal material within the metallic hard mask layer 60 include W, Ti, Ta, Al, Ni, Co, Au, and Ag. Non-limiting examples of elemental metals that can be employed in an intermetallic alloy within the metallic hard mask layer 60 include W, Ti, Ta, Al, Ni, Co, Au, and Ag. Non-limiting examples of metallic nitrides that can be employed in a metallic nitride within the metallic hard mask layer 60 include WN, TiN, TaN, and AlN. Non-limiting examples of metallic carbides that can be employed in a metallic carbide within the metallic hard mask layer 60 include WC, TiC, and TaC. In one embodiment, the metallic hard mask layer 60 can consist essentially of a metallic nitride. In one embodiment, the metallic hard mask layer 60 can consist essentially of TiN.

The metallic hard mask layer 60 can be deposited employing any deposition method known in the art for the material(s) selected for the metallic hard mask layer 60. Deposition methods that can be employed to form the metallic hard mask layer 60 include, but are not limited to, physical vapor deposition, vacuum evaporation, chemical vapor deposition (CVD), molecular beam deposition (MBD), pulsed laser deposition (PLD), liquid source misted chemical deposition (LSMCD), and atomic layer deposition (ALD). The thickness of the metallic hard mask layer 60 can be from 3 nm to 30 nm, although lesser and greater thicknesses can also be employed.

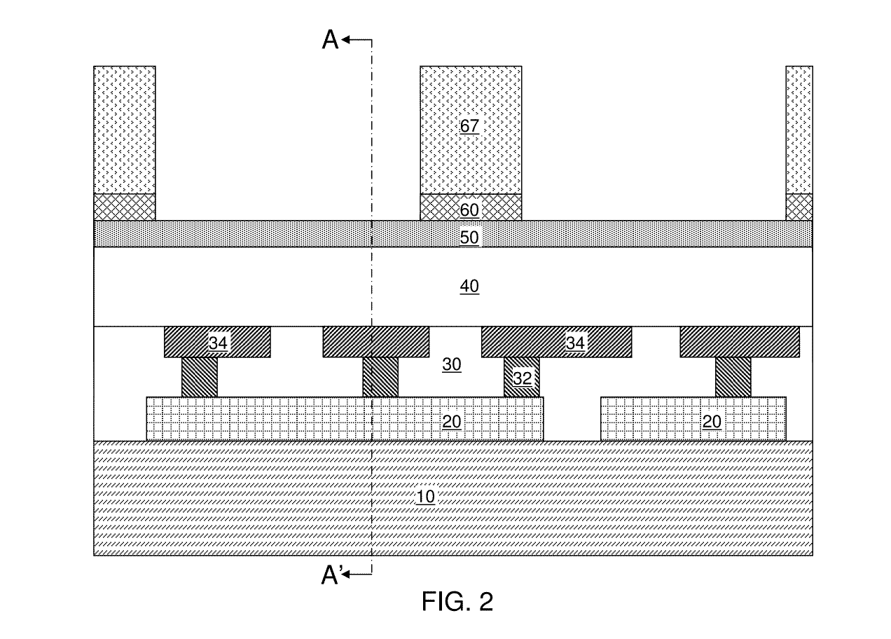

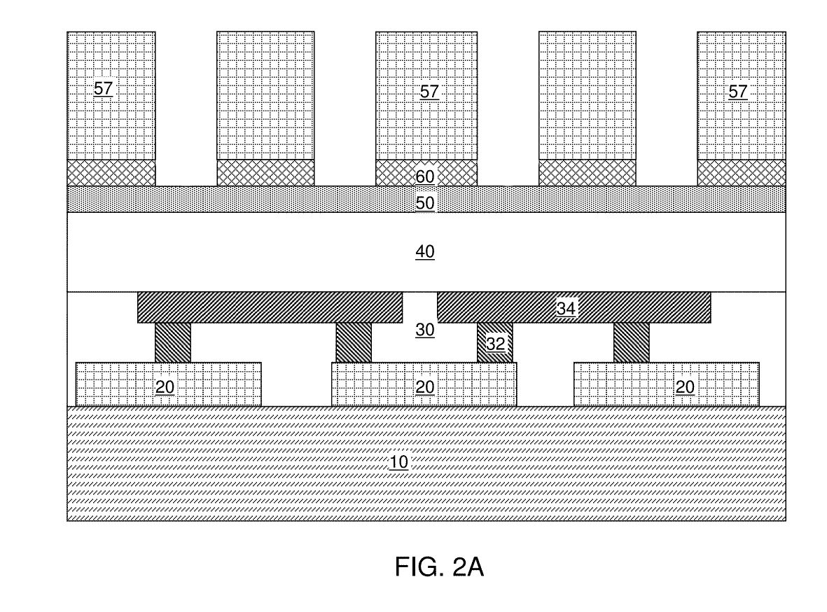

Referring to FIG. 2, a first photoresist layer 57 is applied over the top surface of the stack of material layers (40, 50, 60), and is subsequently patterned lithographically employing lithographic methods known in the art. The pattern in the lithographically patterned first photoresist layer 57 is herein referred to as a first pattern. The first pattern can include openings that are laterally spaced from one another. Alternatively, a trilayer lithography process as known in the art may be employed in which a stack, from bottom to top, of an organic planarization layer, a bottom anti-reflective coating layer, and a photoresist layer is applied over the top surface of the stack of material layers (40, 50, 60), the first patterned in formed in the photoresist layer by lithographic exposure and development and then transferred through the bottom anti-reflective coating layer and the organic planarization layer. In this case, the patterned organic planarization layer can replace the first photoresist layer 57 illustrated in FIG. 2. The bottom anti-reflective layer can be consumed during the pattern transfer into the organic planarization layer, and the patterned organic planarization layer can be employed as an etch mask during a subsequent anisotropic etch process.

In one embodiment, the first pattern can be a line pattern corresponding to horizontal cross-sectional shapes of metal line structures to be subsequently formed within an upper portion of the interlevel dielectric layer 40. In another embodiment, the first pattern can be a via pattern corresponding to horizontal cross-sectional shapes of metal via structures to be subsequently formed within a lower portion of the interlevel dielectric layer 40.

The first pattern is subsequently transferred through the metallic hard mask layer 60 employing an etch, which can be, for example, an anisotropic etch that employs the first photoresist layer 57 as a etch mask. Thus, the first pattern in the first photoresist layer 57 is duplicated in the metallic hard mask layer 60.

In one embodiment, the etch employed to pattern the metallic hard mask layer 60 can terminate at the top surface of the dielectric cap layer 50 upon detection of the top surface of the dielectric cap layer 60 by an optical spectroscopic measurement. In this case, the top surface of the dielectric cap layer 50 can be substantially coplanar throughout the entirety thereof. Alternatively, a fixed overetch time may be programmed into the anisotropic etch such that, upon detection of the physical exposure of a top surface of the interlevel dielectric layer 40, the anisotropic etch terminates upon expiration of the predetermined overetch time. The predetermined overetch time and/or the chemistry of the etch can be selected not to etch through the dielectric cap layer 50. The first photoresist 57 can be removed, for example, by ashing.

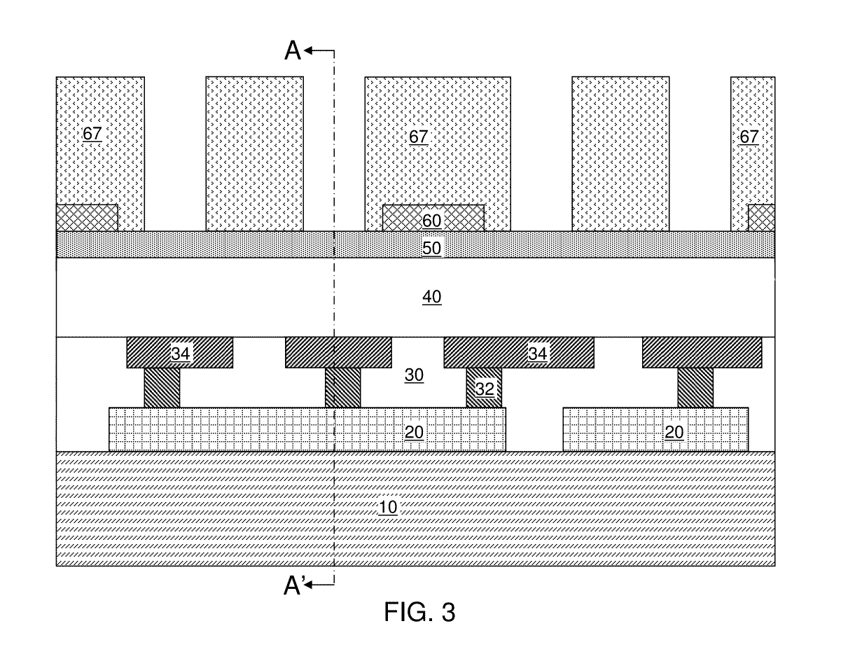

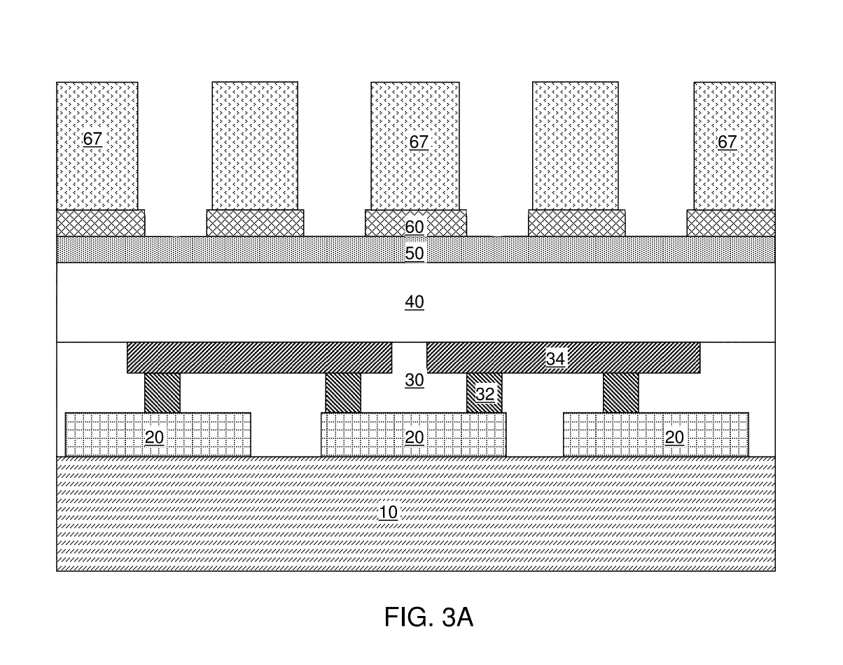

Referring to FIGS. 3 and 3A, a second photoresist layer 67 is applied over the patterned metallic hard mask layer 60 and the dielectric cap layer 50, and is subsequently patterned lithographically. The pattern in the lithographically patterned second photoresist layer 67 is herein referred to as a second pattern. The second pattern can include openings that are laterally spaced from one another. Alternatively, a trilayer lithography process as known in the art may be employed in which a stack, from bottom to top, of an organic planarization layer, a bottom anti-reflective coating layer, and a photoresist layer is applied over the top surface of the stack of material layers (40, 50, 60), the first patterned in formed in the photoresist layer by lithographic exposure and development and then transferred through the bottom anti-reflective coating layer and the organic planarization layer. In this case, the patterned organic planarization layer can replace the first photoresist layer 57 illustrated in FIG. 2. The bottom anti-reflective layer can be consumed during the pattern transfer into the organic planarization layer, and the patterned organic planarization layer can be employed as an etch mask during a subsequent anisotropic etch process.

In one embodiment, the first pattern can be a line pattern and the second pattern can be a via pattern corresponding to horizontal cross-sectional shapes of metal via structures to be subsequently formed within a lower portion of the interlevel dielectric layer 40. In another embodiment, the first pattern can be a via pattern and the second pattern can be a line pattern corresponding to horizontal cross-sectional shapes of metal line structures to be subsequently formed within an upper portion of the interlevel dielectric layer 40.

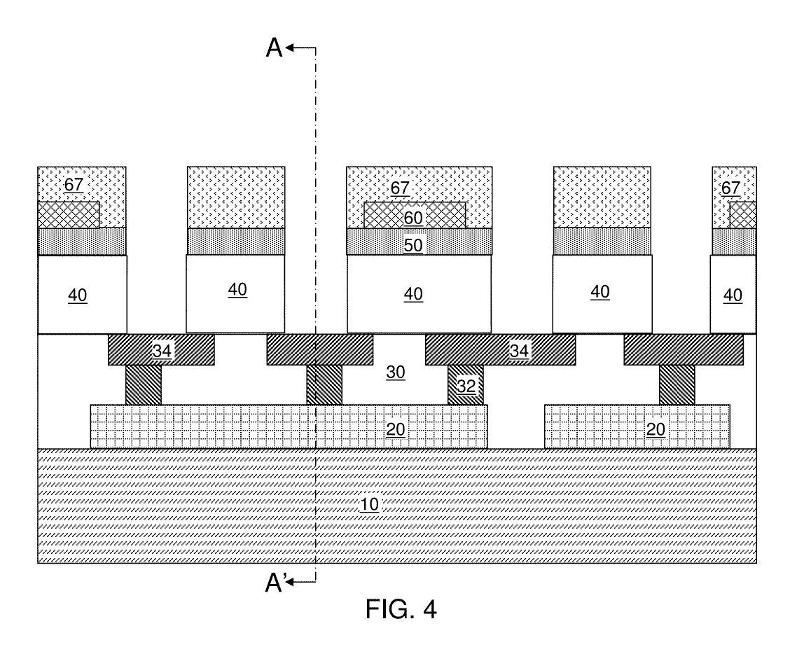

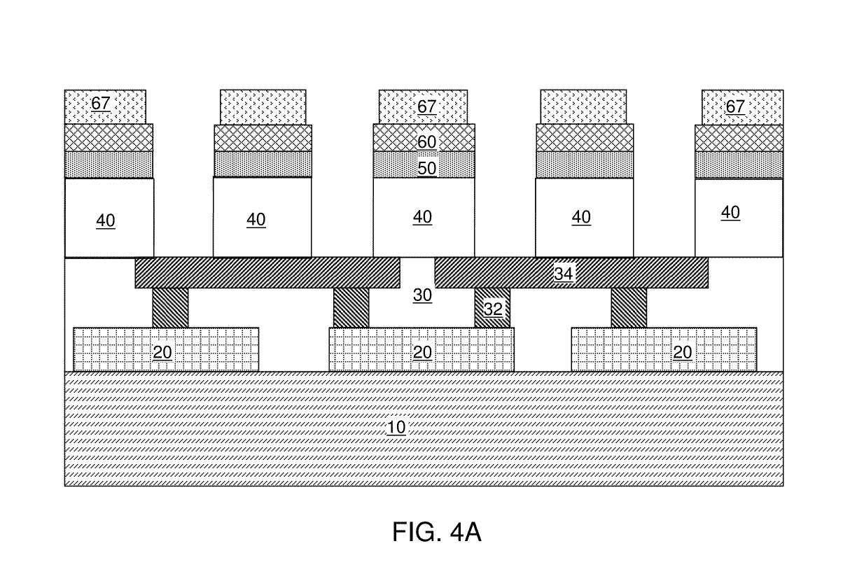

Referring to FIGS. 4 and 4A, an anisotropic etch is performed to transfer the combination of the first pattern and the second pattern into the dielectric cap layer 50 and the interlevel dielectric layer 40. In the exemplary illustration of FIGS. 4 and 4A, the first pattern is transferred through the entirety of the dielectric layer 40, but this is not strictly necessary. In an equally common practice, the first pattern may be transferred only partially through the interlevel dielectric layer 40, with the completion of the transfer occurring during the subsequent transfer of the second pattern as described further below. In one embodiment, the anisotropic etch can be performed in multiple steps. For example, in a first step of the anisotropic etch, a composite pattern generated by an intersection of the first pattern in the metallic hard mask layer 60 and the second pattern in the second photoresist layer 67 is transferred through the dielectric cap layer 50. The areas of the second pattern are the areas in which opening in the metallic hard mask layer 60 and the openings in the second photoresist layer 67 overlap. Physically exposed portions of the metallic hard mask layer 60 may be eroded. The second photoresist layer 67 can be partially, or fully, consumed during the first step of the anisotropic etch. The dielectric cap layer 50 is patterned with the composite pattern.

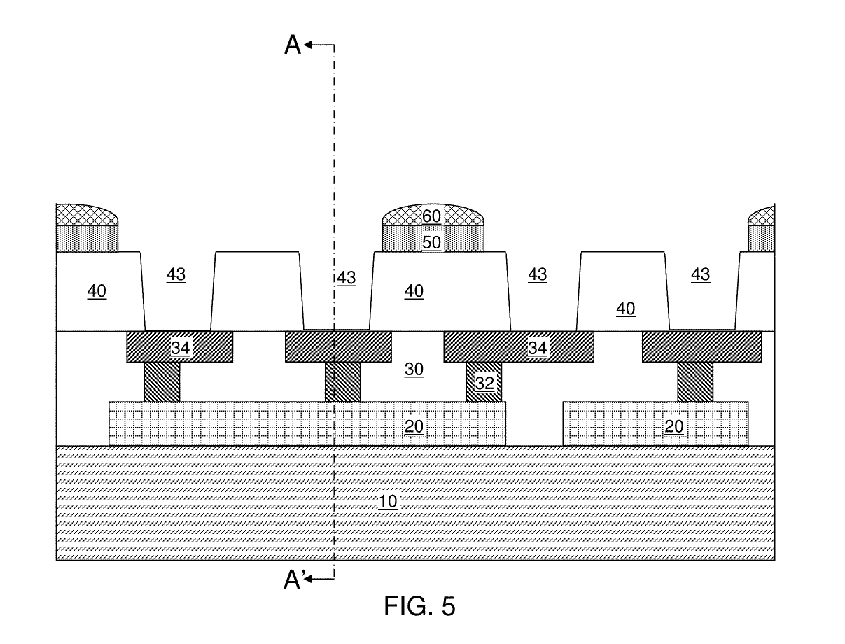

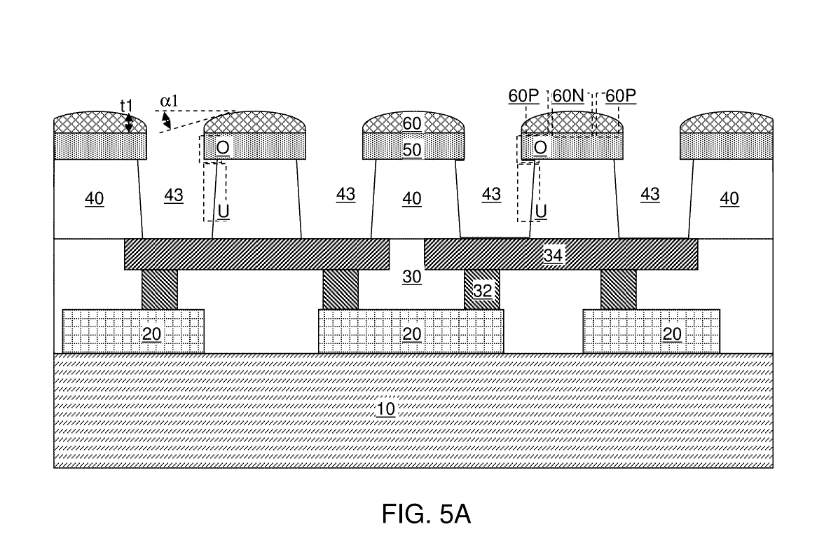

Referring to FIGS. 5 and 5A, a second step of the anisotropic etch is performed. Once the dielectric cap layer 50 is patterned with the composite pattern, physically exposed portions of the interlevel dielectric layer 40 are recessed to form trenches 43 having a bottom surface that does not contact the bottommost surface of the interlevel dielectric layer 40. The composite pattern in the dielectric cap layer 50 is replicated in the upper portion of the interlevel dielectric layer 40.

During or subsequent to the recessing of the physically exposed portions of the interlevel dielectric layer 40, any remaining portions of the second photoresist layer 67 are consumed or removed, and physically exposed portions of the dielectric cap layer 50 are patterned employing the metallic hard mask layer 60 as an etch mask. Thus, the first pattern in the metallic hard mask layer 60 is duplicated in the dielectric cap layer 50. Thus, while an upper portion of the interlevel dielectric layer 40 is patterned with the composite pattern, the dielectric cap layer 50 is patterned with the first pattern.

The physically recessed portions of the interlevel dielectric layer 40 have the composite pattern. During the second step of the anisotropic etch, the physically exposed portions of the interlevel dielectric layer 40 are primarily vertically recessed and collaterally laterally recessed. The collateral lateral recessing of the physically exposed portions of the interlevel dielectric layer 40 causes formation of an undercut region U underneath peripheral portions of the dielectric material layer 50. In one embodiment, the collateral lateral etching of the interlevel dielectric layer 40 may occur because a typical anisotropic etch includes an isotropic etch component due to statistical deviation of the direction of reactive ions from a perfectly vertical direction. Additionally or alternatively, the collateral lateral etching of the interlevel dielectric layer 40 may occur due to chemical reactions between etchant gases and the material of the interlevel dielectric layer 40 (which can be, for example, organosilicate glass) and/or by chemical modification of physically exposed sidewalls of the trenches 43 which may can cause the chemically modified portions of the interlevel dielectric layer 40 to be etched in a subsequent wet etch step that is performed to remove residual portions of the metallic hard mask layer 60 or to clean physically exposed surfaces in preparation for a subsequent process. Thus, a trench 43 can include an undercut region U that is formed directly underneath an overhang portion O of the dielectric cap layer 50.

Physically exposed portions of the metallic hard mask layer 60 are eroded. The erosion of the physically exposed portions of the metallic hard mask layer 60 can be more severe at peripheral portions of the metallic hard mask layer 60 than at non-peripheral portions. As the anisotropic etch reaches a stage at which the top surface of the metallic hard mask layer 60 becomes physically exposed, the remaining portion of the metallic hard mask layer 60 can develop faceted top surfaces at peripheries that laterally surround the openings through the stack of the metallic hard mask layer 60 and the dielectric cap layer 50. The faceting of the metallic hard mask layer 60 can be induced by a greater rate of thinning of the metallic hard mask layer 60 at peripheral portions 60P than at non-peripheral portions 60N. The greater thinning of the metallic hard mask layer 60 at the peripheral portions 60P may be induced by the second pattern. Specifically, portions of the metallic hard mask layer 60 that are physically exposed at the processing step of FIGS. 3 and 3A become thinner than the portions of the metallic hard mask layer 60 that are protected by the second photoresist layer 67 during an early stage of the first step of the anisotropic etch. In addition, the etch rate of the second step of the anisotropic etch may be pattern-factor dependent, and thus, may be greater at peripheral portions 60P of the metallic hard mask layer 60 than at non-peripheral portions 60N of the metallic hard mask layer 60. As used herein, “faceting” of a surface refers to a change of an initially horizontal surface to an angled surface having a finite angle with respect to a horizontal plane. A “faceted” surface refers to a surface on which faceting has occurred.

In one embodiment, the faceted top surfaces of the metallic hard mask layer 60 can have a first variable angle α1 that increases with a lateral distance from a periphery of the metallic hard mask layer 60. Further, upon transfer of the second pattern through the metallic hard mask layer 60 and the dielectric cap layer 50, the remaining portions of the metallic hard mask layer 60 can have a variable thickness, which is herein referred to as a first variable thickness t1. The first variable thickness t1 increases with a lateral distance from a periphery of the remaining portion of the metallic hard mask layer 60.

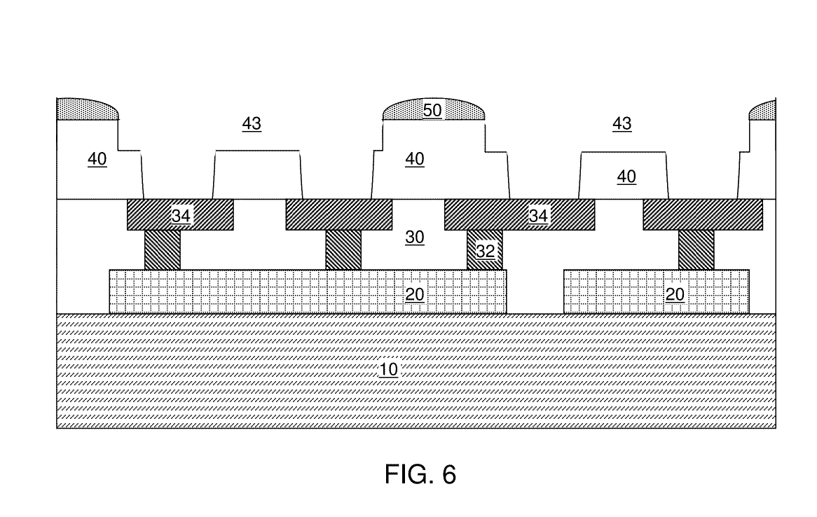

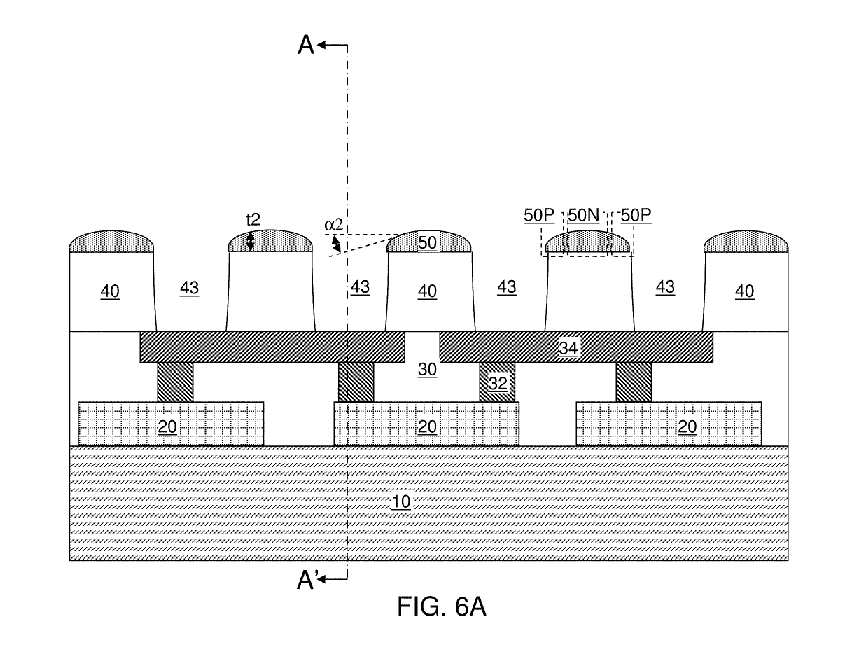

Referring to FIGS. 6 and 6A, a third step of the anisotropic etch is performed to further recess the portions of the interlevel dielectric layer 40 corresponding to the areas of the openings in the first pattern, and to transfer the second pattern in the vertical stack of the metallic hard mask layer 60 and the dielectric cap layer 50 into an upper portion of the interlevel dielectric layer 40. The trenches 43 become expanded during the third step of the anisotropic etch. In one embodiment, the trenches 43 can become dual damascene trenches in which a line trench formed in the upper portion of the interlevel dielectric layer 40 is merged with at least one via cavity formed in the lower portion of the interlevel dielectric layer 40. The trenches 43 can extend from the topmost surface of the interlevel dielectric layer 40 to the bottommost surface of the interlevel dielectric layer 40.

The metallic hard mask layer 60 is further eroded during the third step of the anisotropic etch, and may be completely or partially removed by the third step of the anisotropic etch. In one embodiment, the metallic hard mask layer 60 is completely removed by the end of the third step of the anisotropic etch. Alternatively, if the metallic hard mask layer 60 is not completely removed during the second anisotropic etch, an isotropic etch such as a wet etch may be employed to remove any remaining portions of the metallic hard mask layer 60. The chemistry of the wet etch can be selected to effectively remove the metallic material of the metallic hard mask layer 60 while minimizing collateral etching of the dielectric material of the interlevel dielectric layer 40.

In addition to partial or complete etching of the metallic hard mask layer 60 during the third step of the anisotropic etch, the overhang portions O (See FIG. 5A) of the dielectric cap layer 50 can be collaterally etched by the third step of the anisotropic etch. The remaining portions of the dielectric cap layer 50 overlie the top surface of the interlevel dielectric layer 40 after the third step of the anisotropic etch. Thus, the entire bottom surface of each remaining portion of the dielectric cap layer 50 can be in physical contact with a top surface of the interlayer dielectric layer 40. In one embodiment, a periphery of a bottom surface of the remaining portion of the dielectric cap layer 50 can coincide with a periphery of the top surface of the interlevel dielectric layer 40 around a trench 43 after the third step of the anisotropic etch. In one embodiment, the etch rate of the third step of the anisotropic etch can be pattern-factor dependent, and can be greater at a peripheral portion 50P of the dielectric cap layer 50 than at a non-peripheral portion 50N of the dielectric cap layer 50.

The chemistry of the third step of the anisotropic etch can be selected to provide collateral etching of the dielectric cap layer 50 with pattern factor dependency while providing anisotropic etching of the metallic hard mask layer 60. In one embodiment, the third step of the anisotropic etch can employ a combination of Cl₂ and an inert gas selected from He and Ar. The chlorine based etch chemistry has shown lesser selectivity in the etch rate between metal films and dielectric films during the course of testing performed in the course of the research leading to the present disclosure. The reduction in selectivity across metallic films and dielectric films through the use of the combination of Cl₂ and the inert gas enables collateral etching of the overhang portions O of the dielectric cap layer 50.

In another embodiment, the third step of the anisotropic etch can employ a combination of Cl₂ and a hydrocarbon gas. The hydrocarbon gas can be selected from, but is not limited to, methane, ethane, acetylene, propane, cyclopropene, methylacetylene, and propadien. The RF energy supplied to a process chamber performing the anisotropic etch can be selected to induce formation of HCl by a reaction of Cl₂ and the hydrocarbon gas during the third step of the anisotropic etch. The HCL-generating etch chemistry has shown lesser selectivity in the etch rate between metal films and dielectric films during the course of testing performed in the course of the research leading to the present disclosure. As is the case with the etch chemistry employing the combination of Cl₂ and an inert gas, the reduction in selectivity across metallic films and dielectric films enable collateral etching of the overhang portions O of the dielectric cap layer 50.

The remaining portion of the dielectric cap layer 50 has a variable thickness, which is herein referred to as a second variable thickness t2. The second variable thickness t2 increases with a lateral distance from a periphery of the remaining portion of the dielectric cap layer 50. Further, the remaining portion of the dielectric cap layer 50 can have a faceted top surface at a periphery thereof. The faceted top surface can have a variable angle, which is herein referred to as a second variable angle α2. The second variable angle α2 increases with a lateral distance from the periphery.

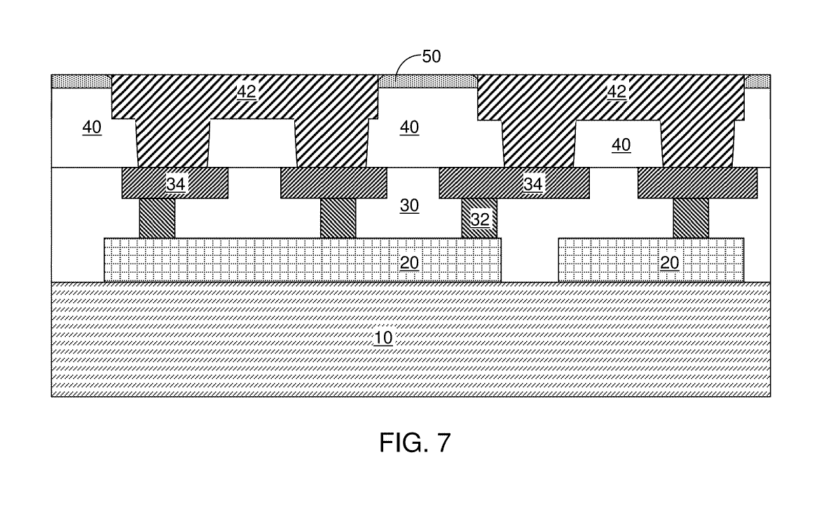

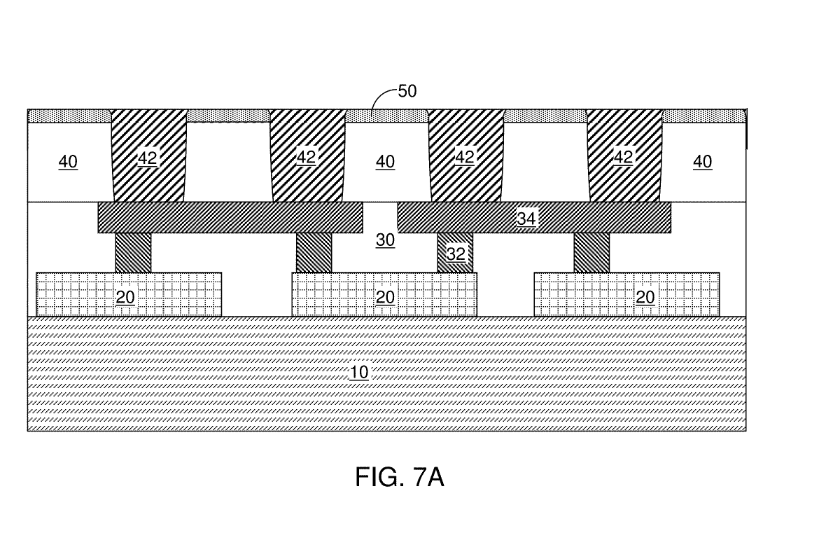

Referring to FIG. 7, after removal of the overhang portion O (See FIG. 5A) of the dielectric cap layer 50 and formation of faceted top surfaces in the dielectric cap layer 50, at least one metallic material is deposited within the trenches 43. The at least one metallic material can include a metallic liner material and/or a conductive fill material. The metallic liner material can be a metallic nitride such as TiN, TaN, and WN, or a metallic carbide such as TiC, TaC, and WC, or a combination or a stack thereof. The conductive fill material can include, for example, copper, tungsten, or aluminum. Each of the at least one metallic materials can be deposited physical vapor deposition (PVD), chemical vapor deposition (CVD), atomic layer deposition (ALD), vacuum evaporation, electroplating, electroless plating, or a combination thereof. Optionally, a non-metallic liner material may be employed in lieu of, or in conjunction with, a metallic liner material as known in the art.

The at least one metallic material is planarized, for example, by chemical mechanical planarization employing the dielectric cap layer 50 as a stopping layer or consuming the dielectric cap layer 50 and stopping by other means within the interlevel dielectric 40. The remaining portions of the at least one metallic material constitute various metallic material portions 42, which are metal interconnect structures. In one embodiment, the metal interconnect structures can be integrated line and via structures.

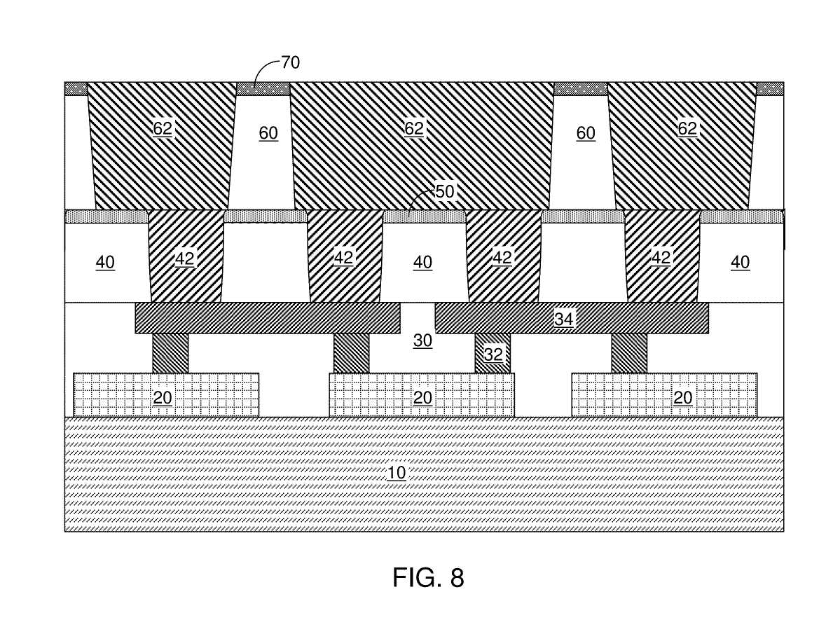

Referring to FIG. 8, another interlevel dielectric layer 60, another dielectric cap layer 70, and additional metal interconnect structures 62 can be formed over the top surface of the dielectric cap layer 50 by repeating the processing steps of FIGS. 1, 2, 3 and 3A, 4 and 4A, 5 and 5A, 6, and 6A. Further, the method of embodiments of the present disclosure may be repeated at more than one metal interconnect level.

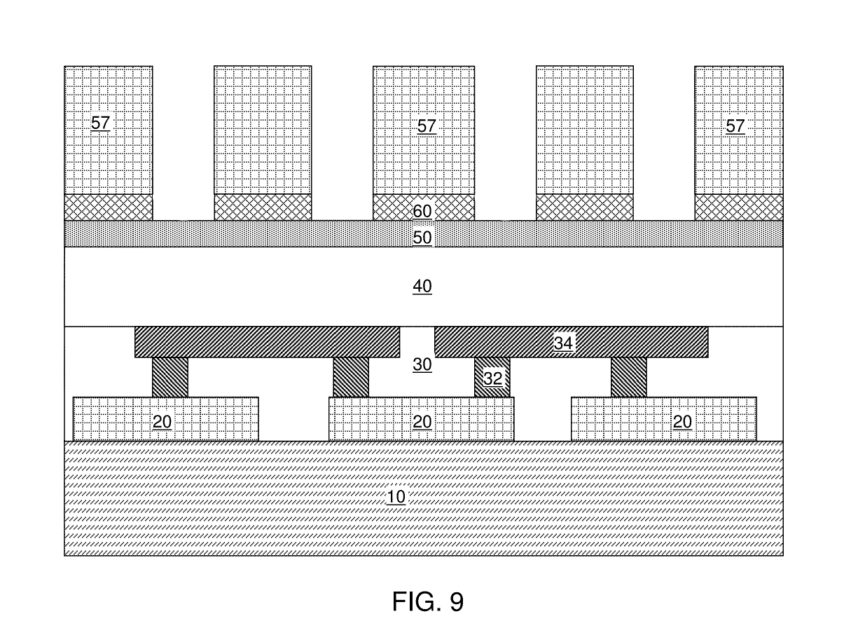

Referring to FIG. 9, a second exemplary structure according to a second embodiment of the present disclosure can be derived from the first exemplary structure of FIG. 2 by employing a via pattern for the first pattern instead of a line pattern.

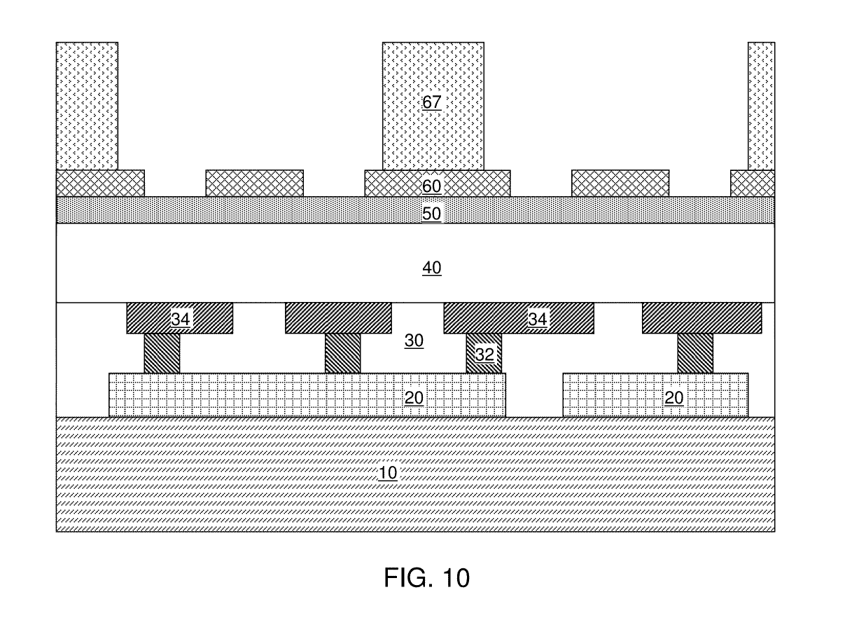

Referring to FIG. 10, the processing steps of FIGS. 3 and 3A are performed employing a line pattern for a second pattern instead of a line pattern.

Subsequently, the processing steps of FIGS. 4, 4A, 5, 5A, 6, and 6A are performed. The composite pattern of the intersection of the first pattern and the second pattern is transferred through the dielectric cap layer 50 by a first step of the anisotropic etch. Then, the composite pattern is transferred into an upper portion of the interlevel dielectric layer 40 and the second pattern is transferred into the dielectric cap layer 50 by a second step of the anisotropic etch. The second photoresist layer 67 is consumed during the first step of the anisotropic etch or before the end of the second step of the anisotropic etch. During a third step, the composite pattern is transferred through the lower portion of the interlevel dielectric layer 40 and the second pattern is transferred through the upper portion of the interlevel dielectric layer 40. The resulting structure can be identical to the first exemplary structure illustrated in FIGS. 6 and 6A. Subsequently, the processing steps of FIGS. 7 and 7A, and optionally 8 can be performed to provide a same structure as the first exemplary structure illustrated in FIGS. 7 and 7A or FIG. 8.

The methods of embodiments of the present disclosure eliminate overhang portions of the dielectric cap layer 50 during the third step of the anisotropic etch corresponding to the processing steps of FIGS. 6 and 6A. Removal of the overhanging portions of the dielectric cap layer 50 can eliminate the danger of void formation during the filling of the trenches 43 with the at least one conductive material at the processing step of FIGS. 7 and 7A. Elimination of voids in the metallic material portions 42 filling the trenches 43 helps adhesion of the metallic material portions 42 to the interlevel dielectric layer 40, and also improves reliability of the metallic material portions 42 by preventing ingress of foreign materials into a seam in metallic material portions that would otherwise be present.

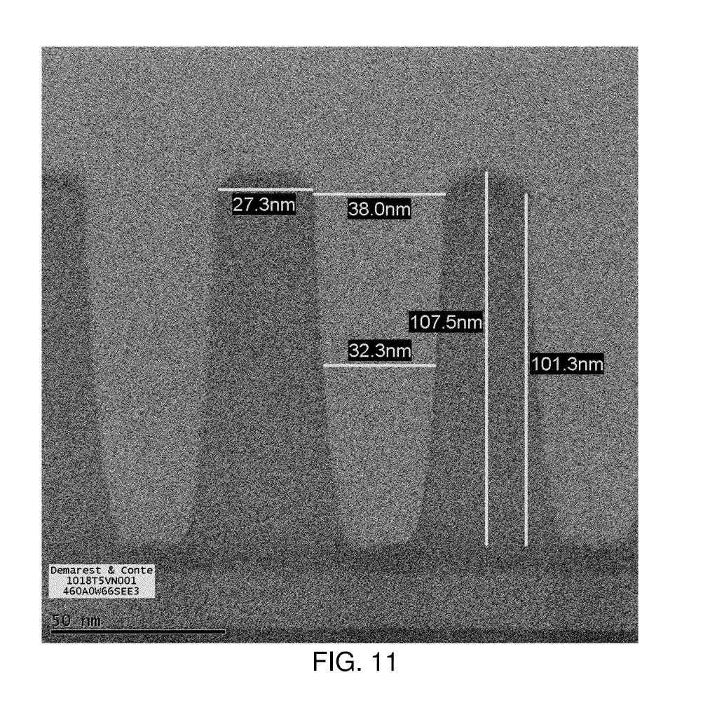

Referring to FIG. 11, a scanning electron micrograph (SEM) of a sample manufactured employing a processing sequence of the present disclosure is shown after deposition of a metallic material in a trench and prior to planarization. The SEM illustrates absence of any overhang in a dielectric cap layer (e.g. a portion above a horizontal bar labeled as “27.3 nm,” and absence of any void in a metallic material portion (e.g., a portion in which two horizontal bars labeled “38.0 nm” and “32.3 nm” are present).

While the disclosure has been described in terms of specific embodiments, it is evident in view of the foregoing description that numerous alternatives, modifications and variations will be apparent to those skilled in the art. Each of the various embodiments of the present disclosure can be implemented alone, or in combination with any other embodiments of the present disclosure unless expressly disclosed otherwise or otherwise impossible as would be known to one of ordinary skill in the art. Accordingly, the disclosure is intended to encompass all such alternatives, modifications and variations which fall within the scope and spirit of the disclosure and the following claims.

What is claimed is:

1. A method of forming a metal interconnect structure comprising:
forming a stack including at least, from bottom to top, an interlevel dielectric layer and a dielectric cap layer over a substrate;
patterning said dielectric cap layer to form an opening therein;
forming a trench employing an anisotropic etch that anisotropically etches a material of said interlevel dielectric layer, wherein said trench includes an undercut region that is formed in a step of said anisotropic etch directly underneath an overhang portion of said dielectric cap layer around said opening; and
removing said overhang portion of said dielectric cap layer during another step of said anisotropic etch, wherein a remaining portion of said dielectric cap layer overlies a top surface of said interlevel dielectric layer after said anisotropic etch.

2. The method of claim 1, wherein said remaining portion of said dielectric cap layer has a variable thickness that increases with a lateral distance from a periphery of said remaining portion of said dielectric cap layer after said anisotropic etch.

3. The method of claim 1, wherein said remaining portion of said dielectric cap layer has a faceted top surface at a periphery after said anisotropic etch.

4. The method of claim 4, wherein said faceted top surface has a variable angle that increases with a lateral distance from said periphery.

5. The method of claim 1, wherein said dielectric cap layer comprises a material selected from silicon oxide, silicon oxynitride, silicon nitride, a nitrogen-containing non-porous organosilicate glass, and a dielectric metal oxide.

6. The method of claim 5, wherein said interlevel dielectric layer comprises porous or non-porous organosilicate glass.

7. The method of claim 1, wherein a periphery of a bottom surface of said remaining portion of said dielectric cap layer coincides with a periphery of a top surface of said interlevel dielectric layer around said trench after said anisotropic etch.

8. The method of claim 1, wherein an etch rate of said anisotropic etch is pattern-factor dependent and is greater at a peripheral portion of said dielectric cap layer than at a non-peripheral portion of said dielectric cap layer.

9. The method of claim 1, further comprising forming a metallic hard mask layer on a top surface of said dielectric cap layer as a component of said stack.

10. The method of claim 9, further comprising patterning said metallic hard mask layer with a first pattern, wherein said opening extends through said metallic hard mask layer.

11. The method of claim 10, further comprising transferring said first pattern into an upper portion of said interlay dielectric layer during said anisotropic etch.

12. The method of claim 10, further comprising:
forming a patterned photoresist layer including a second pattern over said metallic hard mask layer and said dielectric cap layer after formation of said opening; and
transferring said second pattern at least through said metallic hard mask layer and said dielectric cap layer, wherein a remaining portion of said metallic hard mask layer has a variable thickness.

13. The method of claim 12, wherein said variable thickness increases with a lateral distance from a periphery of said remaining portion of said metallic hard mask layer.

14. The method of claim 12, wherein said remaining portion of said metallic hard mask layer has a faceted top surface at a periphery, wherein said faceted top surface has a variable angle that increases with a lateral distance from said periphery.

15. The method of claim 12, further comprising removing said remaining portion of said metallic hard mask layer employing during said another step, wherein a remaining portion of said dielectric cap layer has another variable thickness.

16. The method of claim 15, wherein said another step of said anisotropic etch employs a combination of Cl₂ and an inert gas selected from He and Ar.

17. The method of claim 15, wherein said another step of said anisotropic etch employs a combination of Cl₂ and a hydrocarbon gas.

18. The method of claim 17, further comprising inducing formation of HCl by a reaction of Cl₂ and said hydrocarbon gas during said another step of said anisotropic etch.

19. The method of claim 1, further comprising depositing a metallic material within said trench after removal of said overhang portion.

20. The method of claim 19, further comprising forming a metallic material portion within said trench by removing a portion of said deposited metallic material employing said remaining portion of said dielectric cap layer as a stopping layer in a planarization process.
